(19) United States
(12) Patent Application Publication
(10) Pub. No.: US 2005/0119032 A1
(43) Pub. Date: Jun. 2, 2005

(54) Optical messaging

(76) Inventor: Maija Airas, Never Groben (DE)

Correspondence Address: Geza C. Ziegler, Jr.;PERMAN & GREEN, LLP, 425 Post Road, Fairfield, CT, 06824, US

(21) Appl. No.: 10/910,914

(22) Filed: Aug. 4, 2004

Related U.S. Application Data
(63) Continuation of application No. PCT/EP03/09534, filed on Aug. 28, 2003.

(51) Int. Cl. H03D 1/00

(52) U.S. Cl. 455/566; 455/550.1

(57) ABSTRACT

A mobile communication terminal comprises a housing with a user interface thereon. The user interface has a keypad and a display arranged on the housing. The housing is further provided with a large light emitting matrix. Symbols that can be recognized by the human eye at a distance of about 4 meters or more can be displayed on the large light emitting matrix. The phone can be provided with a plurality of colored lights instead of or together with the large light emitting matrix. The large light emitting matrix and colored lights can be used to send optical messages to persons other than the user of the phone. The phone can alternatively or in addition be provided with a power LED. The light emitted by the power LED can modulated manually or automatically, in accordance with any given code. The optical messages from the matrix, the colored lights and from the power LED can be captured by a camera of a second terminal end decoded therein.

The present invention relates to messaging from a mobile communication terminal to a person other than the user of the terminal or to another mobile terminal. The invention relates in particular to messaging using visible light to a remote person other than the user of the terminal and to messaging using visible light to another terminal.

### BACKGROUND OF THE INVENTION

Messaging from a mobile communication terminal, such as a mobile phone, to a person other than the user at moderate distances is hitherto unknown. Audible messaging from the mobile communication terminal to the user is though a standard feature for modern mobile phones used e.g. to inform the user that a call or a messaging has arrived. Sound is though hardly useful for communicating a message from a terminal to a person other than the user of the mobile communication terminal. If the person is close enough it would be easier for the user of the mobile communication terminal to speak to the person. If the person is somewhat remote, the high sound levels would need be used, which is impractical given the typical loudspeaker capacity of the mobile communication terminals, and undesirable because of noise pollution.

The use of RF or IR electromagnetic waves for sending a message from one mobile communication terminal to another is also known but requires standardization and permissions from the authorities.

### DISCLOSURE OF THE INVENTION

Against this background, it is an object of the present invention to provide a mobile communication terminal with an alternative messaging capacity. This object is achieved in accordance with claim 1 by providing a mobile communication terminal comprising a housing, a user interface having a keypad and a display arranged on the housing, and said housing being provided with a large light emitting matrix capable representing symbols that can be recognized by the human eye at a distance of about 4 meters or more.

The large matrix allows symbols to be recognized by the human eye at distances where this would be impossible with a conventional display because the conventional displays of mobile communication devices are ergonomically optimized by selecting the appropriate display size, font size, resolution and brightness for reading at a distance of about 40 to 50 cm form the users eyes. With the present invention it is rendered possible to send a message to a person other to than the user of the mobile terminal, also at distances of over four meters. This allows for a new communication channel, that does not pollute the RF band nor the acoustical band.

The large light emitting matrix can be a matrix of light emitting diodes.

Alternatively, the large light emitting matrix can be a matrix of electroluminescent fields.

It is also possible to use a large light emitting matrix that comprises organic light emitting devices.

The mobile communication terminal may further comprise an application enabling a user to compose symbols for displaying on the large light emitting matrix.

The mobile communication terminal can also comprise an editor program allowing a user to select a symbol to be displayed or to compose a sequence or string of symbols to be displayed.

The large symbols to be displayed can be part of a string of characters, preferably displayed as a scrolling text.

Alternatively, the large symbols to be displayed can be displayed in a blinking fashion.

The mobile communication terminal may further comprise an editor for composing large symbols, or sequences of elements of the matrix to be lit, preferably allowing selection of the brightness, color and length of the lit period.

The housing can be a one piece construction, with the keypad and display on one housing side and the light emitting matrix on another housing side, preferably a housing side opposite to the housing side on which the keypad and the display are arranged.

Alternatively, the housing can be a construction with two housing parts that can move relative to one another, in which the light emitting matrix is divided over two housing parts that can be arranged to form one large light emitting matrix.

With a construction with two housing parts that can move relative to one another, it is also possible to combine the light emitting matrix and the display to form one larger light emitting matrix.

It is another object of the present invention to provide a cover for releasable attachment a mobile communication terminal, that renders it possible to provide for an alternative messaging capacity with the mobile terminal. This object is achieved in accordance with claim 15 by providing a cover for releasable attachment a mobile communication terminal, said cover comprising an interface for communicating with the mobile communication terminal and a large light emitting matrix capable of representing symbols that can be recognized by the human eye at a distance of several meters or more.

It is yet another object of the invention to provide a mobile communication terminal with an alternative messagin gcapacity. This object is achieved in accordance with claim 16 by providing a mobile communication terminal comprising a display that forms part of the user interface of the terminal, and means for displaying large symbols on the display that can be recognized by the human eye at a distance of 2 meters or more.

The means for displaying large symbols allows symbols to be recognized by the human eye at distances where this would be impossible with a conventional display. Thus, it becomes possible to send a message to a person other to than the user of the mobile terminal, also at distances over four meters. This allows for a new communication channel, that does not pollute the RF band nor the acoustical band.

The display can be a backlit color or monochrome LCD display.

The means for displaying large symbols may comprise an editor program allowing a user to select a symbol to be displayed or to compose a sequence or string of symbols to be displayed.

The brightness and contrast settings of the display may be maximized when the large symbols are displayed.

It is yet another object of the invention to provide a further mobile communication terminal with an alternative messaging capacity. This object is achieved in accordance with claim 20 by providing a mobile communication terminal comprising a housing, a user interface having a keypad and a display, and means to emit sequences of activation of powerful light sources in a plurality of colors that can be recognized from about twenty meters distance or more by the human eye.

The mobile communication terminal may further comprise an editor program to compose the sequences of activation of powerful light.

The editor program may allow manipulation of the length and intensity of activations in the sequence.

The means to emit sequences of powerful light may comprise a plurality of light emitting diodes in different colors.

It is another object of the present invention to provide a further cover for releasable attachment a mobile communication terminal, that renders it possible to provide for an alternative messaging capacity with the mobile terminal. This object is achieved in accordance with claim 24 by providing a cover for releasable attachment to a mobile communication terminal, the cover comprising an interface for communicating with the mobile communication terminal and a plurality of strong lights with different colors that can be detected by the human eye from a distance of 20 meters or more.

It is yet another object of the invention to provide another mobile communication terminal with an alternative messaging capacity. This object is achieved in accordance with claim 25 by providing a mobile communication terminal comprising a housing, a user interface having a keypad and a display, and a powerful light source that can be modulated.

The powerful light source can be detected by another device, such as a mobile phone equipped with a camera, or by the human eye at a large distance, of e.g. one hundred meters or more. Thus, it becomes possible to send optical messages over large distances.

The modulation of the light source may be manually controlled by a user, preferably by manipulating a key of the keypad.

Alternatively, the modulation of the light source is electronically controlled, preferably by a controller in accordance with an encoded signal stored in the terminal. The signal may be encoded in Morse code.

The mobile communication terminal may further comprise an application for encoding text messages or the like.

It is another object of the present invention to provide another cover for releasable attachment a mobile communication terminal, that renders it possible to provide for an alternative messaging capacity with the mobile terminal. This object is achieved in accordance with claim 31 by providing a cover for releasable attachment to a mobile communication terminal, the cover comprising an interface for communicating with the mobile communication terminal and a powerful light source that can be modulated via said interface.

It is yet another object of the invention to provide an alternative messaging method from a mobile communication terminal to a person other than the user of the terminal. This object is achieved in accordance with claim 32 by providing a method of sending a message from a mobile communication terminal to a person other than the user of the mobile communication terminal, the mobile communication terminal being provided with a light source of which the intensity and/or the color can be modulated, comprising the steps of positioning the mobile communication terminal such that the light source can be seen by the intended recipient, encoding the message to be sent to obtain an encoded signal, and modulating the intensity and/or the color of the light source in accordance with the encoded signal.

It is yet another object of the invention to provide an alternative messaging method from a first mobile communication terminal to a second mobile communication terminal. This object is achieved in accordance with claim 33 by providing a method of sending a message from a first mobile communication terminal to a second mobile communication terminal, the first mobile communication terminal comprising a light source that can be modulated, the second mobile communication terminal comprising a camera capable of capturing still or motion video, comprising the steps of encoding a message to be send in accordance with a given code to obtain a coded signal, transmitting the coded signal by modulating the intensity or color of the light emitter, capturing the coded signal with the camera of the second mobile phone and decoding the message in the second mobile phone.

The code used can be Morse code.

It is yet another object of the invention to provide a mobile communication terminal with an alternative messaging receiving capacity. This object is achieved in accordance with claim 35, by providing a mobile communication terminal comprising a camera capable of capturing still or motion video and an application capable of decoding a signal received as modulated light by the camera.

It is yet another object of the invention to provide a further mobile communication terminal with an alternative messaging receiving capacity. This object is achieved in accordance with claim 36, by providing a mobile communication terminal comprising a camera capable of capturing still or motion video and a character recognition application capable of recognizing characters or symbols captured by the camera.

The character recognition application is preferably capable of recognizing characters in scrolling texts.

It is yet another object of the invention to provide an alternative messaging method from a mobile communication terminal to person other than the user of the mobile communication terminal. This object is achieved in accordance with claim 39 by providing a method of sending a message from a mobile communication terminal to a person other than the user of the mobile communication terminal, the mobile communication terminal being provided with a large light emitting matrix, comprising the steps of positioning the mobile communication terminal such that the large light emitting matrix can be seen by the intended recipient, and displaying a symbol or a sequence of symbols on said large light emitting matrix.

It is yet another object of the invention to provide an alternative messaging method between mobile communication terminals. This object is achieved in accordance with claim 40 by providing a method of sending a message from a first mobile communication terminal to a second mobile communication terminal, the first mobile communication terminal being provided with a large light emitting matrix, and the second mobile communication terminal being provided with a camera capable of capturing still or motion video and a character recognition application capable of recognizing characters or symbols captured by the camera, comprising the steps of positioning the first and second mobile communication terminals such that symbols displayed on the large light emitting matrix can be captured by the camera, displaying a symbol or a sequence of symbols on said large light emitting matrix, capturing the symbol or sequence of symbols with said camera, and processing the captured symbols with said character recognition application.

Further objects, features, advantages and properties of the mobile communication terminals, releasable covers and methods for messaging according to the invention will become apparent from the detailed description.

### BRIEF DESCRIPTION OF THE DRAWINGS

In the following detailed portion of the present description, the invention will be explained in more detail with reference to the exemplary embodiments shown in the drawings, in which:

FIG. 1 is a perspective view of the front of a mobile phone in accordance with a first preferred embodiment of the invention,

FIG. 2. is a perspective view of the rear of the mobile phone shown in FIG. 1,

FIG. 3 is a perspective view of the front of a mobile phone in accordance with a second preferred embodiment of the invention,

FIG. 4 is a perspective view of the rear of the mobile phone shown in FIG. 3,

FIG. 5 is a perspective view of a mobile phone in accordance with a third preferred embodiment of the invention,

FIG. 6 is a perspective view of the side of the mobile phone shown in FIG. 5,

FIG. 7 is a perspective view of the rear of the mobile phone shown in FIG. 5,

FIG. 8 is a block diagram of the essential components of a mobile phone according to the invention,

FIG. 8a is a block diagram of the optical message application software structure,

FIG. 9 illustrates the procedure of sending a message from a mobile phone to a person other than the user of the mobile communication terminal,

FIG. 10 illustrates the procedure of sending a message from one mobile phone to another,

FIGS. 11 and 12 illustrate the process of data input and conversion for sending as an optical message,

FIGS. 13 and 14 illustrate a large display with symbols thereon,

FIGS. 15a, FIG. 15b and FIG. 15d illustrate a table used in a voice recognition training application, and

FIGS. 16a and FIG. 16b illustrate the operation of voice commands for displaying symbols on the large light emitting matrix.

### DETAILED DESCRIPTION

In the following detailed description, a mobile communication terminal according to the invention in the form of a hand portable phone, preferably a cellular/mobile phone, will be described by the preferred embodiments.

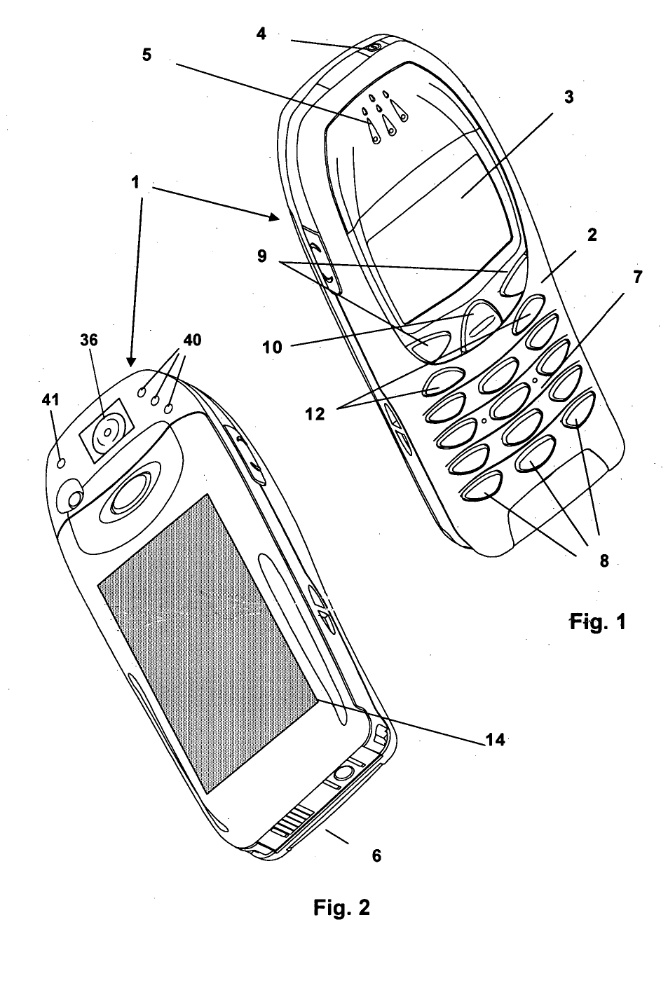

FIG. 1 shows a first preferred embodiment of a phone according to the invention. The phone 1 has a housing 2 on which the elements of the user interface are arranged. The user interface comprises a keypad 7, a display 3, an on/off button 4 a speaker 5, and a microphone 6 (openings present at the bottom of the phone and therefore visible in FIG. 2 only). The phone 1 according to the preferred embodiment is adapted for communication via a cellular network, such as e.g. the GSM 900/1800 MHz network.

The keypad 2 has a first group of keys 8 as alphanumeric keys, two softkeys 9, a cursor navigation key 10 (scroll up/down), and on-hook and off-hook keys 12. The present functionality of the soft keys 9 is shown in separate fields (softkey-labels) in the display 3 just above the softkeys 9. The softkeys 9 are a multifunction keys and their present function depends on the state of the phone 1. The sof tkeys 9 give access to the menu and the phonebook and have call and message handling functions in certain states of the phone 1.

FIG. 2 shows the rear side of the phone of FIG. 1, with a large light emitting matrix 14. According to the first preferred embodiment the large light emitting matrix 14 is formed by a large number of light emitting diodes (LED). It is however possible to use any bright light matrix, such as a backlit TFT matrix, a matrix of electroluminescent fields or a matrix of organic light emitting devices. The rear side of the phone is further provided wit a camera of which only the lens 36 is visible. The camera is a digital still image and motion video camera. An array of LEDs 40 with different colors is integrated in the upper part of the rear side of the mobile phone 1. The rear side of the mobile phone is further provided with high output LED 41.

The symbols to be displayed on the large light emitting matrix 14 are selected in a dedicated light messaging application described in further detail below that is accessible thought the menu structure of the phone. The application allows e.g. the selection of symbols, and creation of texts that can be either statically displayed or in a scrolling fashion. The application also allows for selection of other effects such as blinking, color, brightness and duration.

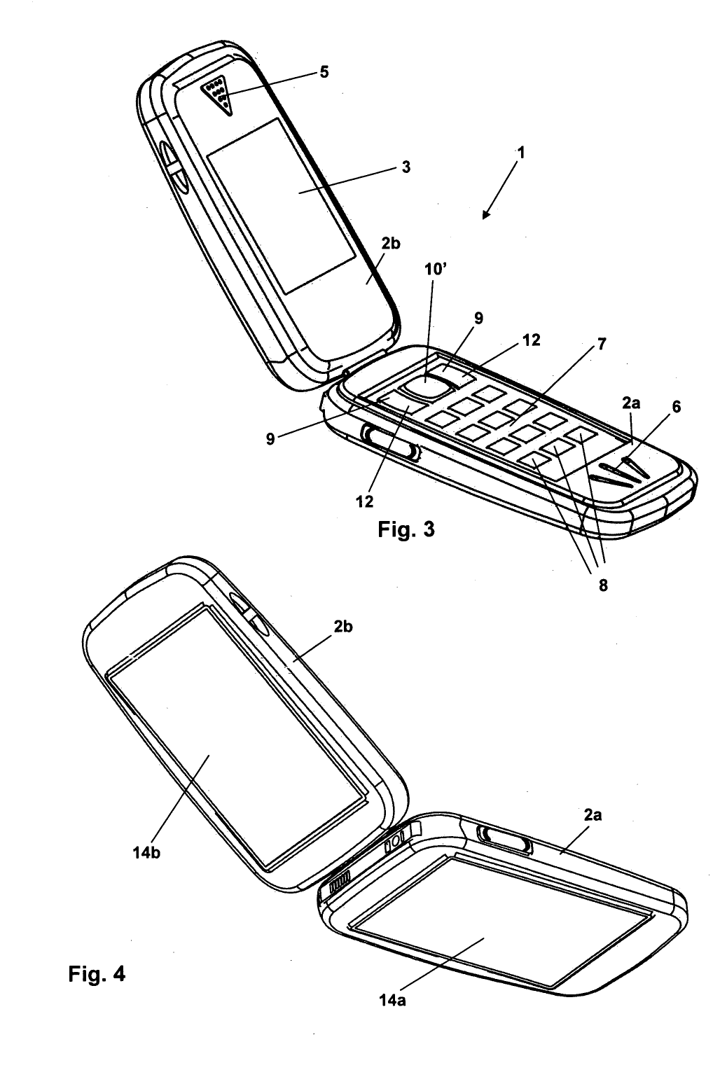

FIGS. 3 and 4 illustrate a second preferred embodiment of the invention in the form of a so called fold phone. In FIG. 3 the front side of the opened phone is shown to have a user interface that is identical to user interface according to the first embodiment with the exception of the scroll key 10′ which has four scrolling directions in the second preferred embodiment (left, right, up and down). The display 3 and the speaker 5 are arranged on the upper housing part 2b whereas the remainder of the user interface is arranged on the lower housing part 2a. The housing parts are connected by a simple hinge.

FIG. 4 shows that the rear side of the phone is provided with two light emitting matrixes 14a and 14b that together form a single large light emitting matrix when the phone 1 is folded open.

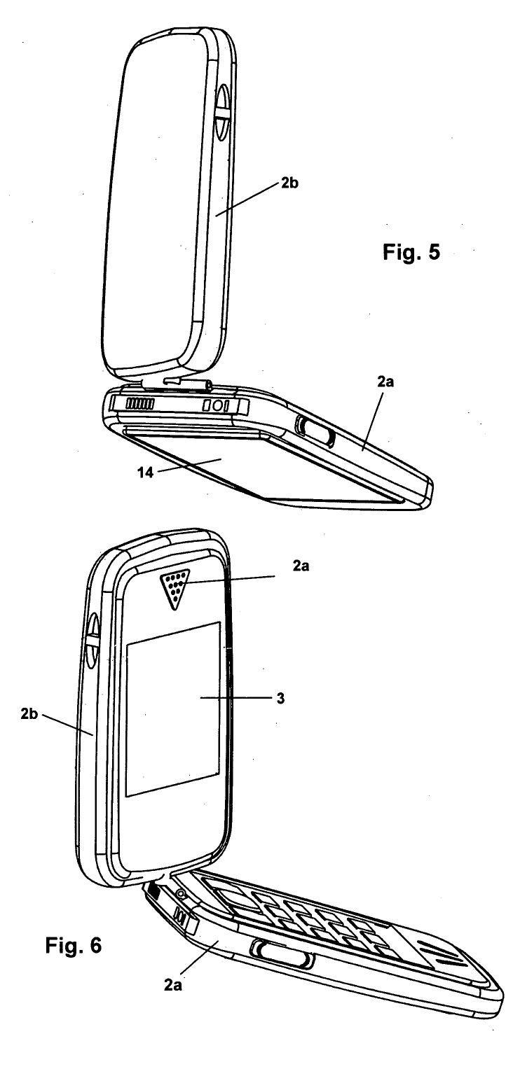

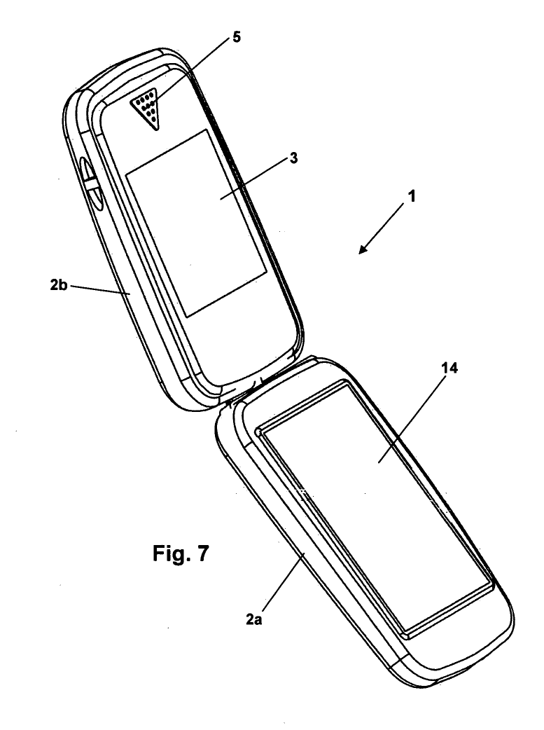

FIGS. 5 to 7 illustrate a third preferred embodiment of the invention in the form of a so called swivel phone. In this embodiment the upper housing part 2b is connected to the lower housing part by a swivel so that the upper part 2b can both fold and swivel relative to the lower housing part 2a. The display 3 can therefore be used as the conventional user interface display or—when turned around—be combined with a large light emitting matrix 14 on the back of the lower housing part 2a to form an even larger light emitting matrix (cf. FIG. 7).

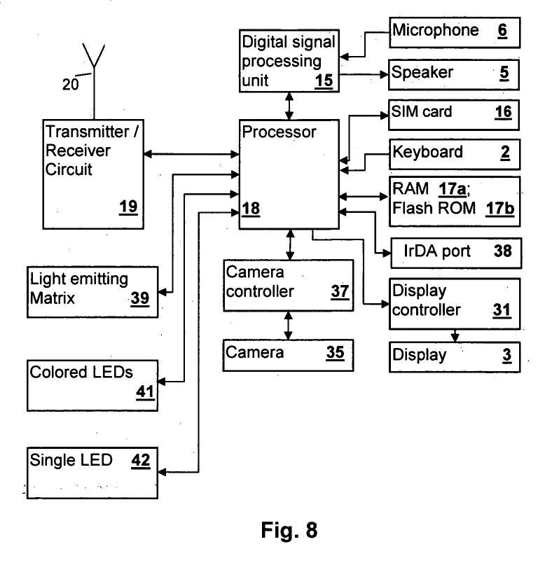

FIG. 8 schematically shows the components of a preferred embodiment of the phone in a schematic manner to assist in understanding of the invention. The processor 18 controls the communication with the network via the transmitter/receiver circuit 19 and an internal antenna 20.

The microphone 6 transforms the user's speech into analogue signals, the analogue signals formed thereby are A/D converted in an A/D converter (not shown) before the speech is encoded in a digital signal processing unit 15 (DSP). The encoded speech signal is transferred to the processor 18, which i.e. supports the GSM terminal software. The processor 18 also forms the interface to the peripheral units of the apparatus, including a RAM memory 17a and a Flash ROM memory 17b, a SIM card 16, the display 3 and the keypad 2 (as well as data, power supply, etc.). The digital signal-processing unit 15 speech-decodes the signal, which is transferred from the processor 18 to the speaker 5 via a D/A converter (not shown). The processor 18 interfaces also with the camera 35 through the camera controller 37, to the light emitting matrix 39, the colored LEDs 41 and the single power LED 42.

The features of the phone are generally accessed through a menu with a structure that comprises a main menu loop with menu items and submenu loops with submenu items. The scroll key 10 allows the user to jump to the preceding or succeeding menu item. The function of the left softkey 12 in the menu- or submenu loops is “Select” whilst the function of the right softkey 12 is “Back”.

The items of the main menu loop are e.g. “Phonebook”, “Messages”, “Call register”, “Profiles”, “Settings”, “Organizer” etc. There can be many more features on the phone requiring further menu items but these have no relevance to the present invention and are therefore not discussed here. The menu item “Messages” gives access to a messages related submenu loop. The submenu items in the messages related submenu loop are e.g. “Text messages”, “Multimedia messages”, “Chat”, “Message settings” and “Optical messages”. The submenu item “Optical messages” gives access to a optical messages related submenu loop.

The optical messages related submenu loop comprises the submenu items “Morse optical messages”, “Multiple color LED messages” and “Display messages”.

The “Morse optical messages” submenu item gives access to a Morse optical messages related submenu that comprises the submenu items, “Create message”, “Sent messages”, “Inbox” and “Manually encoded messages” and “. The “Create messages” item gives access to an editing application that allows the user to select the text for the message to be sent. This editor application may use a predictive text editor to assist the user in entering text with the alphanumerical keyboard. After entering message text the functionality of the left softkey 12 changes to “Options” and gives access to an options submenu comprising the submenu items “Send”, “Sending options” “Save message” and “Clear text”. Under the submenu item “Sending options” the user can select the sending speed and the type of code to be used. The submenu item “Send” activates the transmission by starting the application that encodes the texts and controls the power LED 41 accordingly. The “Manually encoded messages” sets the phone in a manual transmitting state in which the power LED 41 is active when the left softkey is pressed. The user can thus send e.g. Morse code signals by manipulating the left softkey 9.

The “Displayed optical messages” submenu item gives access to a displayed optical messages related submenu that comprises the submenu items, “Create message” and “Sent messages”. The “Create messages” item gives access to a graphic editor application 72 that allows the user to select the symbols to be displayed. The editor application 72 allows the entry of regular letters and numbers to form words and sentences but is not directed towards the creation of longer text. The editor application comprises however a special symbol selecting feature that assist the user in selecting symbols such as smileys, hearts emergency signals, pictograms, barcodes and any other graphic symbols that a user may wish to display as an optical message. The application contains a symbol library with standardized pictogram lexicons which the user may select symbols from. The image library/gallery can be downloaded from a server such as the Club Nokia® server. The graphical editor application comprises:
a gallery selector, for enabling a user to select a particular gallery (preferably of up to eight clip-art pictures), view each of the clip-art pictures in the gallery, and for selecting a gallery to be communicated as a message;
a clip-art picture editor, for enabling a user to select a particular clip-art picture (after first selecting a gallery), modify the clip-art picture, and then save the clip-art picture either in place of the original clip-art picture or as a clip-art picture in another (possibly new) gallery; and a
gallery communicator, for sending OTA a selected gallery and for receiving a transmitted gallery (and, optionally, automatically recognizing a received object as a gallery), and for storing a received gallery in a memory location in the receiving device (and for asking the user which gallery to replace if insufficient memory is available to store the receive gallery without writing over an existing gallery), and also including a formatter for converting a clip-art gallery from the format in which the clip-art galleries are stored in the gallery folder to any of a number of other formats (such as e.g. from an 72×28 GMS picture format to an 86×52 screen saver format or to an 72×28 screen saver format, or to other formats in use).

The gallery selector includes a browser function (imparting to the clip-art picture manager a browse mode) enabling a user to view and select clip-art pictures in a gallery, as opposed to enabling a user to edit clip-art pictures or change the content of a gallery (the two latter actions being performed in edit mode using the clip-art picture editor). A graphic editor application of this kind is described in detail in U.S. 2003069004, hereby incorporated by reference.

The editor feature includes user selection of the color, brightness and duration of the symbols to be displayed. The user can also choose the text direction and choose the setting for scrolling texts. After selecting at least one symbol the functionality of the left softkey 12 changes to “Options” and gives access to an options submenu comprising the submenu items “Send”, “Save message” and “Clear message”. The editor application also has a feature for designing custom pictograms to be displayed.

The phone 1 comprises an optical character recognition application (OCR) 73 (FIG. 8a) that allows it to recognize characters in text and symbols captured by the camera 35 such as barcode displayed on the large light emitting matrix 14 of other mobile phones.

The “Multiple color LED messages” submenu item gives access to a Multiple color LED messages related submenu that comprises the submenu items, “Create message” and “Sent messages”. The submenu item “Create messages” gives access to an editing application that allows the user to determine the sequence in which the three colored LEDs 40 will light, the length of each activation and the intensity of the activation. This editor is described in more detail in U.S. Ser. No. 10/096,491 hereby incorporated by reference. The colored LEDs can also be activated upon detection of an incoming call, message or any other event as selected by the user. After selecting at least one LED activation the functionality of the left softkey 12 changes to “Options” and gives access to an options submenu comprising the submenu items “Send”, “Save message” and “Clear message”.

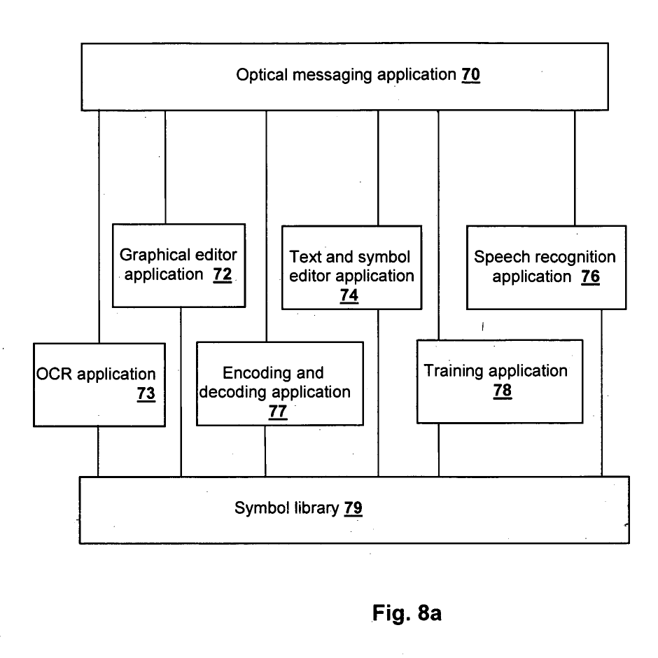

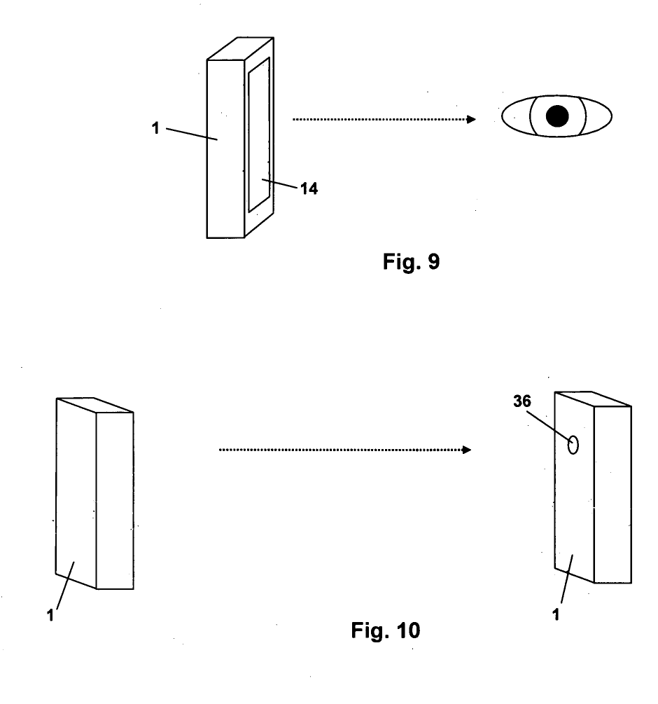

FIG. 9 illustrates how the large light emitting matrix 3 is used to send a message to a person at a distance from the phone 1. The person is represented by an eye only. The user of the phone 1 selects at least one symbol to displayed on the large light emitting matrix 3 and the processor instructs the large light emitting matrix 3 to display the symbol accordingly. Meanwhile the user of the phone 1 directs the large light emitting display 14 towards the person at a distance, and given an unobstructed line of sight, the person at a distance can recognize the displayed symbol. The matrix is large and bright enough for a the human eye to recognize it at over four meters distance under daylight conditions. The symbols can be any known kind, such as numbers letters or other symbols such as smileys, hearts, wings etc.

FIG. 10 illustrates how the power LED 41 is used to send a message from a first mobile phone 1 (the power LED cannot be seen in the present view) to a second mobile phone 1. The power LED 41 is preferably of a highly efficient type that has a narrow light emission angle. This reduces the risk of the light beam to hit the eyes of the user of the second phone.

Alternatively the power LED 41 can be replaced by an arrangement of a large number of LEDs (not shown), e.g. a cluster of 3 or 7 LEDs. The user of the first mobile phone 1 selects a massage text to be sent. The processor 18 encodes the signal into Morse code and modulates the amplitude of the light emitted by the power LED accordingly. Meanwhile the user of the first phone directs power LED 41 towards the second mobile phone 1 and given an unobstructed line of sight, the camera lens 36 of the second mobile phone 1 captures the encoded signal. Preferably, the camera 35 is zoomed to a narrow view angle. The optical signal emitted by the power LED is bright enough for a remotely placed camera to capture it at distances of over 100 meter or more in daylight conditions. The camera may be provided with a narrow pass band filter that matches the wavelength of the power LED 41 in order to reduce interference with other light sources.

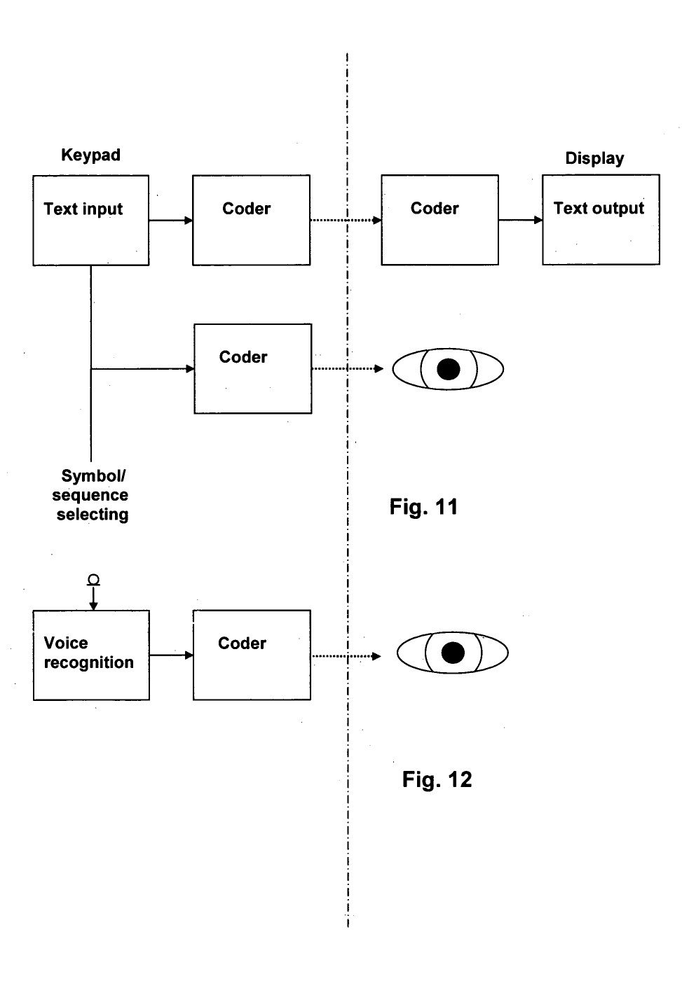

FIG. 11 shows a block diagram of the optical message input to output process. The user may enter a text using the keypad 2, or select a symbol or a sequence as described above. When the user activates the sending procedure, the message to be displayed/send is processed in a coder block 77 that is capable of encoding outgoing messages and decoding incoming messages. The message is then displayed on the large light emitting matrix 14, colored LEDS or on the power LED and received by either a camera of a second mobile phone 1 for it to be decoded by the coder 77, or received by a human eye. When the signal is received by a second mobile phone 1 its coder decodes the signal and displays the text of the received message on the display 3. The coder 77 of the second phone 1 comprises also a character and pictogram recognition program that allow it to recognize text and pictograms. Thus optical messages sent using the large light emitting display 14 can also be captured with a mobile phone.

FIG. 12 illustrates a block diagram of a sound/music related optical message. The input is the ambient sound picked up by the microphone 6. The sound signal is encoded and then displayed on the large display 14 or on the colored LEDS 40 for reception by the human eye. Thus, the mobile phone 1 can operate as a light organ.

The present invention can be used for personal expression, for warning e.g. SOS or other emergency signals, as traffic signals, for information or data exchange, both uni- and bidirectional, point to point and multiple point communication, illumination, advertisement and for group voting.

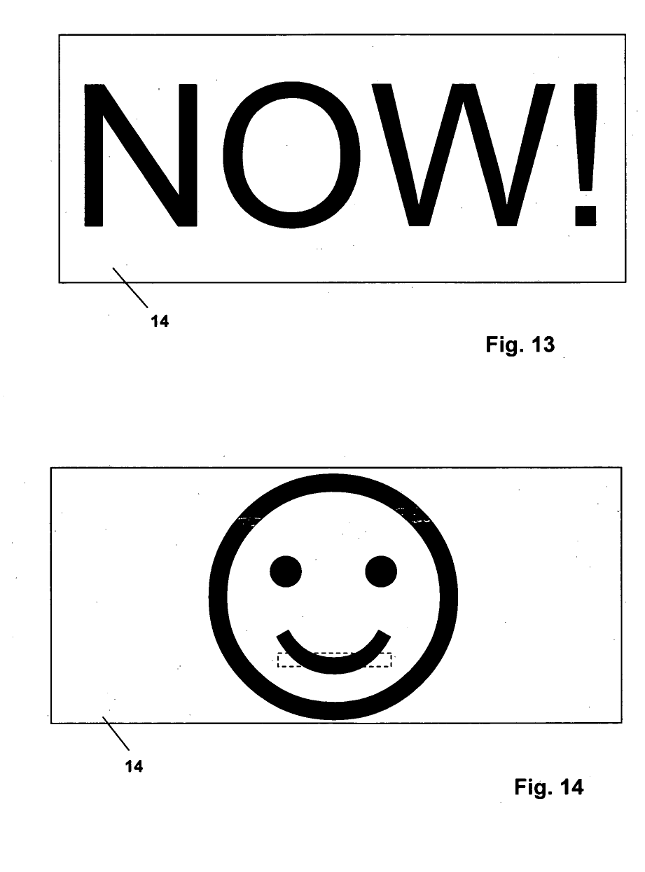

FIGS. 13 and 14 illustrate examples of the type of content that can be displayed on the large display. The example of FIG. 14 is an animation! in this case a smiley that changes between a smiling face and an neutral face, indicated with the interrupted line type. The user may select the speed of the animation to be dependent of the ambient sound picked up by the microphone 6. This allows the animation to be in rhythm with the music in a discotheque or the like.

The software structure of the part of the phone software relating to optical messaging as illustrated in FIG. 8a. The optical message application 70 comprises a graphical editor application 72 for creating new symbols or editing existing symbols from the symbol library 79, a text and symbol editor 74 to create text with or without additional other symbols than text, an optical character recognition application 72 to recognize text and other symbol encoded data, an encoding and decoding application 77, a speech recognition application 76 and a thereto belonging training application 78. All these applications have access to the symbol library 79. The operation of the speech recognition application and the training application 78 will now be described with reference to a practical example.

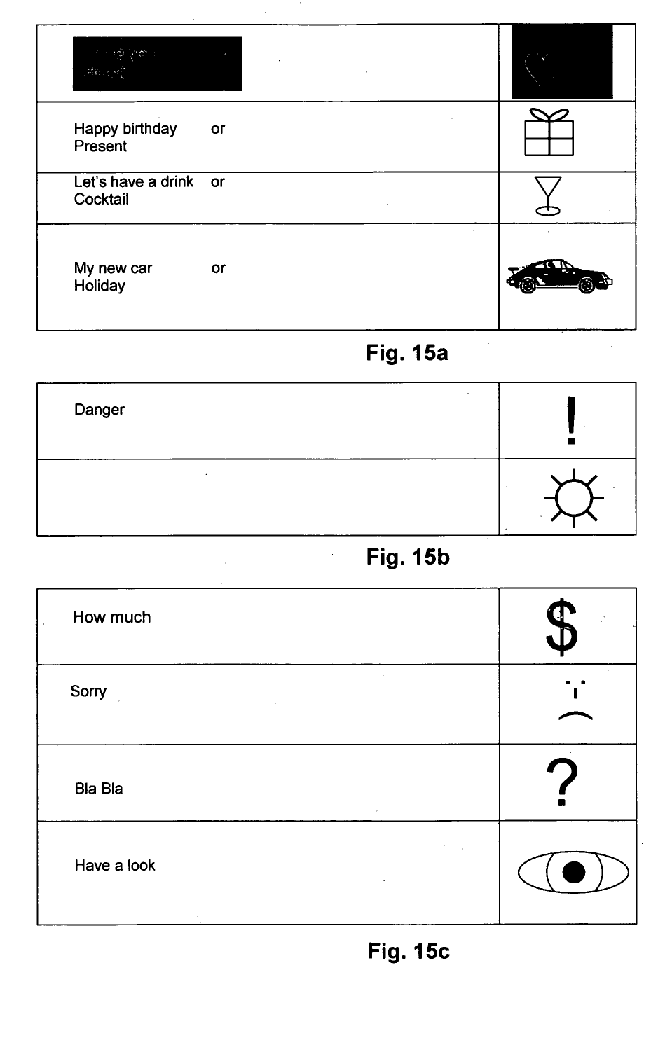

The training application allows the user to store a number of voice controlled symbols. After opening the training application in the optical messaging menu item several different programmable symbol groups such as “for fun”, “for attention” and “for interaction” can be selected. After selecting “for fun” the preferably Java™ based training application displays table as shown in FIG. 15a with fun related symbols from the image library in the right hand column. The left column is initially blank (like the entry for the [symbol] symbol in FIG. 15b). The user highlights one of the rows in the table with the scroll key, in FIG. 15a the first row with the heart symbol is highlighted. The user speaks the text (voice tag) to be assigned to the symbol, and repeats this procedure if necessary until the speech recognition application has recognized the spoken text and displays it in the left column. Then the entry is ready for use with voice commands (described in detail further below). Similarly, the voice tags are added to other symbols in the same group or in other groups as shown in FIG. 15b and 15c. The “for interaction” symbol group of FIG. 15c preferably comprises symbols that are useful for communicating in foreign countries, the native language of which the user does not know.

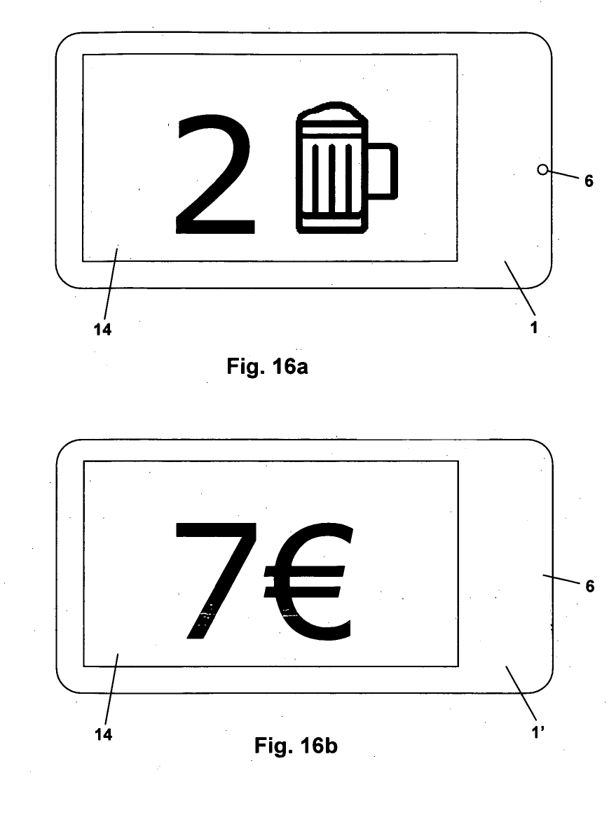

The operation of the voice command application is now described with reference to FIGS. 16a and 16b. The user is for example visiting a noisy overcrowded pub, and ordering drinks requires yelling in order to reach the bartender. Instead the user speaks the text “two beer” into the microphone 6 of his mobile phone 1 and the voice recognition application 70 recognizes the previously stored voice tag and recalls the associated or symbol or symbols. Thus, the optical messaging application 70 displays the number two followed by a stylized beer mug that was stored in the image library 79 on the large display 14. Finally the user raises his arm to hold up the mobile phone 1 to show the bartender his order. The bartender has also a mobile phone 1′ (FIG. 16b) and after placing the two beers on the bar he selects the text “7 [symbol] ” to be displayed on the large light emitting matrix 14 of his mobile phone 1′ and shows it to the user who ordered the two beers.

Although the present invention has been described in detail for purpose of illustration, it is understood that such detail is solely for that purpose, and variations can be made therein by those skilled in the art without departing from the scope of the invention.

Thus, while the preferred embodiments of the devices and methods have been described in reference to the environment in which they were developed, they are merely illustrative of the principles of the inventions. Other embodiments and configurations may be devised without departing from the scope of the appended claims.

1. A mobile communication terminal comprising a housing, a user interface having a keypad and a display arranged on the housing, and said housing being provided with a large light emitting matrix capable representing symbols that can be recognized by the human eye at a distance of about 4 meters or more:

2. A mobile communication terminal according to claim 1, wherein the large light emitting matrix is a matrix of light emitting diodes.

3. A mobile communication terminal according to claim 1, wherein the large light emitting matrix is a matrix of electroluminescent fields.

4. A mobile communication terminal according to claim 1, wherein the large light emitting matrix comprises organic light emitting devices.

5. A mobile communication terminal according to claim 1, wherein the distance at which the human eye can recognize the symbols is more than 5 meters.

6. A mobile communication terminal according to claim 1, further comprising an application enabling a user to compose symbols for displaying on the large light emitting matrix.

7. A mobile communication terminal according to claim 1, further comprising an editor program allowing a user to select a symbol to be displayed or to compose a sequence or string of symbols to be displayed.

8. A mobile communication terminal according to claim 1, wherein the large symbols to be displayed are part of a string of characters, preferably displayed as a scrolling text.

9. A mobile communication terminal according to claim 1, wherein the large symbols to be displayed are displayed in a blinking fashion.

10. A mobile communication terminal according claim 1, further comprising an editor for composing large symbols, or sequences of elements of the matrix to be lit, preferably allowing selection of the brightness, color and length of the lit period.

11. A mobile communication terminal according to claim 1, wherein the housing is a one piece construction, with the keypad and display on one housing side and the light emitting matrix on another housing side, preferably a housing side opposite to the housing side on which the keypad and the display are arranged.

12. A mobile communication terminal according to claim 1, wherein the housing is a construction with two housing parts that can move relative to one another, in which the light emitting matrix is divided over two housing parts that can be arranged to form one large light emitting matrix.

13. A mobile communication terminal according to claim 1, wherein the housing is a construction with two housing parts that can move relative to one another, in which the light emitting matrix and the display can be combined to form one larger light emitting matrix.

14. A mobile communication terminal according to claim 1, further comprises means for generating an animation to be displayed on said display whereby the animation is responsive to ambient sound picked up by the microphone.

15. A cover for releasable attachment a mobile communication terminal, said cover comprising an interface for communicating with the mobile communication terminal and a large light emitting matrix capable of resenting symbols that can be recognized by the human eye at a distance of several meters or more.

16. A mobile communication terminal comprising a display that forms part of the user interface of the terminal, and means for displaying large symbols on the display that can be recognized by the human eye at a distance of 2 meters or more.

17. A mobile communication terminal according to claim 16, wherein the display is a backlit color or monochrome LCD display.

18. A mobile communication terminal according to claim 16, wherein said means for displaying large symbols comprises an editor program allowing a user to select a symbol to be displayed or to compose a sequence or string of symbols to be displayed.

19. A mobile communication terminal according to claim 16 wherein the brightness and contrast settings of the display are maximized when the large symbols are displayed.

20. A mobile communication terminal comprising a housing, a user interface having a keypad and a display, and means to emit sequences of activation of powerful light sources in a plurality of colors that can be recognized from about 20 meters distance or more by the human eye.

21. A mobile communication terminal according to claim 20, further comprising an editor program to compose said sequences of activation of powerful light.

22. A mobile communication terminal according to claim 20, in which the editor program allows manipulation of the length and intensity of activations in the sequence.

23. A mobile communication terminal according to claim 20 , wherein the means to emit sequences of powerful light comprises a plurality of light emitting diodes in different colors.

24. A cover for releasable attachment to a mobile communication terminal, said cover comprising an interface for communicating with the mobile communication terminal and a plurality of strong lights with different colors that can be detected by the human eye from a distance of 20 meters or more.

25. A mobile communication terminal comprising a housing, a user interface having a keypad and a display, and a powerful light source that can be modulated.

26. A mobile communication terminal according to claim 25, in which the modulation of the light source is manually controlled by a user, preferably by manipulating a key of the keypad.

27. A mobile communication terminal according to claim 25, in which the modulated light can be detected by the human eye at a distance of about 100 meters or more.

28. A mobile communication terminal according to claim 25, in which the modulation of the light source is electronically controlled, preferably by a controller in accordance with an encoded signal stored in the terminal.

29. A mobile communication terminal according to claim 28, in which the signal is encoded in Morse code.

30. A mobile communication terminal according to claim 28, further comprising an application for encoding text messages or the like.

31. A cover for releasable attachment to a mobile communication terminal, said cover comprising an interface for communicating with the mobile communication terminal and a powerful light source that can be modulated via said interface.

32. A method of sending a message from a mobile communication terminal to a person other than the user of the mobile communication terminal, the mobile communication terminal being provided with a light source of which the intensity and/or the color can be modulated, comprising the steps of:
positioning the mobile communication terminal such that the light source can be seen by the intended recipient,
encoding the message to be sent to obtain an encoded signal, and
modulating the intensity and/or the color of the light source in accordance with the encoded signal.

33. A method of sending a message from a first mobile communication terminal to a second mobile communication terminal,
the first mobile communication terminal comprising a light source that can be modulated,
the second mobile communication terminal comprising a camera capable of capturing still or motion video, comprising the steps of:
encoding a message to be send in accordance with a given code to obtain a coded signal,
transmitting the coded signal by modulating the intensity or color of the light emitter,
capturing the coded signal with the camera of the second mobile phone and decoding the message in the second mobile phone.

34. A method according to claim 33, wherein the code is Morse code.

35. A mobile communication terminal comprising a camera capable of capturing still or motion video and an application capable of decoding a signal received as modulated light by the camera.

36. A mobile communication terminal comprising a camera capable of capturing still or motion video and a character recognition application capable of recognizing characters or symbols captured by the camera.

37. A mobile communication terminal according to claim 36, in which said character recognition application is capable of recognizing characters in scrolling texts.

38. A mobile communication terminal according to claim 36, wherein the recognizable symbols include Barcode.

39. A method of sending a message from a mobile communication terminal to a person other than the user of the mobile communication terminal, the mobile communication terminal being provided with a large light emitting matrix, comprising the steps of:
positioning the mobile communication terminal such that the large light matrix can be seen by the intended recipient, and
displaying a symbol or a sequence of symbols on said large light emitting matrix.

40. A method of sending a message from a first mobile communication terminal to a second mobile communication terminal, the first mobile communication terminal being provided with a large light emitting matrix, and the second mobile communication terminal being provided with a camera capable of capturing still or motion video and a character recognition application capable of recognizing characters or symbols captured by the camera, comprising the steps of:
positioning the first and second mobile communication terminals such that symbols displayed on the large light matrix can be captured by the camera,
displaying a symbol or a sequence of symbols on said large light emitting matrix,
capturing the symbol or sequence of symbols with said camera, and
processing the captured symbols with said character recognition application.
